(19) United States
(12) Patent Application Publication
(10) Pub. No.: US 2026/0349559 A1
(43) Pub. Date: Nov. 5, 2026

(54) DISPLAY SUBSTRATE AND DISPLAY PANEL

(71) Applicant: BOE TECHNOLOGY GROUP CO., LTD., Beijing (CN)

(72) Inventors: Deshuai Wang, Beijing (CN); Jian Sun, Beijing (CN); Zhen Wang, Beijing (CN); Jian Zhang, Beijing (CN); Zhenhong Xiao, Beijing (CN); Jianyun Xie, Beijing (CN); Xintong Fan, Beijing (CN)

(73) Assignee: BOE TECHNOLOGY GROUP CO., LTD., Beijing (CN)

(21) Appl. No.: 19/487,040

(22) PCT Filed: Apr. 18, 2024
(86) PCT No.: PCT/CN2024/088615

§ 371 Date: Nov. 24, 2025

(30) Foreign Application Priority Data
May 31, 2023 (CN) 202310640152.7

(51) Int. Cl. G06F 3/041; G02F 1/1333; H10D 86/40

(52) U.S. Cl. CPC G06F 3/04164; G02F 1/13338; G06F 3/0412; H10D 86/441

(57) ABSTRACT

Provided are a display substrate and a display panel. The display substrate includes: a display area; a fan-out area located on one side of the display area; multiple display fan-out lines and multiple touch fan-out lines are provided in the fan-out area, the display fan-out lines and the touch fan-out lines are electrically connected to a driver chip respectively; in a direction perpendicular to a plane where a base of the display substrate is located, a distance between at least some of the touch fan-out lines and the base is substantially equal to a distance between the display fan-out lines and the base.

### CROSS-REFERENCE TO RELATED APPLICATIONS

The present application claims priority to Chinese patent application No. 202310640152.7, entitled “DISPLAY SUBSTRATE AND DISPLAY PANEL”, filed on May 31, 2023 before the China National Intellectual Property Administration, which is incorporated herein in its entirety by reference.

### TECHNICAL FIELD

The present application relates to the field of display technology, in particular to a display substrate and a display panel.

### BACKGROUND

In recent years, touch technology has been widely applied in various multimedia electronic products, particularly in portable mobile devices such as smartphones, e-books, and tablets. In the current globalized world, touch panels have evolved into a mature technological industry. As the simplest, most convenient, and intuitive operation method, they have become an extremely popular human-machine interface and multimedia interaction approach. Moreover, touch panels offer advantages such as durability, fast response speed, and space savings by eliminating other input devices.

With the development of display technology, there is an increasing demand for higher performance and aesthetic appeal in display products. Narrow bezels are one of the key factors influencing aesthetics. Compared to non-touch display products, touch display products require more wiring. Currently, the manufacturing process for touch display products with narrow bezels involves significant technical challenges and high costs.

### SUMMARY

Embodiments of the present application adopt technical solutions described below.

In a first aspect, at least one embodiment of the present application provides a display substrate, including:
a display area;
a fan-out area located on one side of the display area;
multiple display fan-out lines and multiple touch fan-out lines are provided in the fan-out area, the display fan-out lines and the touch fan-out lines are electrically connected to a driver chip respectively;
in a direction perpendicular to a plane where a base of the display substrate is located, a distance between at least some of the touch fan-out lines and the base is substantially equal to a distance between the display fan-out lines and the base.

In at least one embodiment of the present application, the touch fan-out lines include first-type touch fan-out lines and second-type touch fan-out lines, orthogonal projections of the display fan-out lines and orthogonal projections of the first-type touch fan-out lines on the base do not overlap with each other, and the orthogonal projections of the display fan-out lines and the orthogonal projections of the second-type touch fan-out lines on the base overlap with each other.

In at least one embodiment of the present application, a minimum distance between the first-type touch fan-out lines and the base is substantially equal to a minimum distance between the display fan-out lines and the base, and a minimum distance between the second-type touch fan-out lines and the base is less than the minimum distance between the display fan-out lines and the base.

In at least one embodiment of the present application, a minimum distance between the first-type touch fan-out lines and the base is substantially equal to a minimum distance between the display fan-out lines and the base, and a minimum distance between the second-type touch fan-out lines and the base is greater than the minimum distance between the display fan-out lines and the base.

In at least one embodiment of the present application, a number of the first-type touch fan-out lines is less than a number of the second-type touch fan-out lines;

the first-type touch fan-out lines and the second-type touch fan-out lines are arranged in different film layers, and at least some of the first-type touch fan-out lines are arranged in a same film layer, and the second-type touch fan-out lines are arranged in a same film layer.

In at least one embodiment of the present application, each of the display fan-out lines and the first-type touch fan-out lines includes a first segment and a second segment that are electrically connected, the first segment extends to a boundary between the display area and the fan-out area, and the second segment is electrically connected to the driver chip;
the first segment and the second segment of the same fan-out line are arranged in different film layers; adjacent first segments are arranged in different film layers, and adjacent second segments are arranged in different film layers.

In at least one embodiment of the present application, the number of the first-type touch fan-out lines is one-Mth of a total number of all touch fan-out lines, and M is a positive integer equal to or greater than 2;
all the touch fan-out lines are divided in a way that every M touch fan-out lines form a group, with one touch fan-out line in the group being the first-type touch fan-out line.

In at least one embodiment of the present application, the number of the first-type touch fan-out lines is one third of the total number of all touch fan-out lines; all the touch fan-out lines are divided in a way that a (3N+1)th touch fan-out line, a (3N+2)th touch fan-out line and a (3N+3)th touch fan-out line form a group;
the (3N+1)th touch fan-out line and the (3N+3)th touch fan-out line are the second-type touch fan-out lines, and the (3N+2)th touch fan-out line is the first-type touch fan-out line; the orthogonal projections of the (3N+1)th touch fan-out line and the (3N+3)th touch fan-out line on the base overlap with the orthogonal projections of the display fan-out lines on the base, while the orthogonal projection of the (3N+2)th touch fan-out line on the base does not overlap with the orthogonal projections of the display fan-out lines on the base; N is an integer.

In at least one embodiment of the present application, the display area is provided with multiple touch electrode rows arranged in an array, and each touch electrode row comprises multiple touch electrodes;
all the touch electrode rows are divided in a way that a (3N+1)th row, a (3N+2)th row and a (3N+3)th row form a group, each group of touch electrode rows comprises a touch electrode row where all the touch electrodes are electrically connected to the first-type touch fan-out lines.

In at least one embodiment of the present application, the number of the first-type touch fan-out lines is one-Mth of a total number of all touch fan-out lines, and M is a positive integer equal to or greater than 2;
multiple touch fan-out lines arranged in a direction intersecting with a direction from the display area to the fan-out area form a touch fan-out line group, all the touch fan-out lines in some of the touch fan-out line groups are the first-type touch fan-out lines, and all the touch fan-out lines in some other touch fan-out line groups are the second-type touch fan-out lines.

In at least one embodiment of the present application, the fan-out area includes a first central region and two first edge regions located on both sides of the first central region, a direction from the first central region to the first edge regions intersects with a direction from the display area to the fan-out area;
some of the first-type touch fan-out lines are located in one of the first edge regions, and some other first-type touch fan-out lines are located in the other first edge region, and the second-type touch fan-out lines are located in the first central region.

In at least one embodiment of the present application, the display area is provided with multiple touch electrode columns arranged in an array, and each touch electrode column comprises multiple touch electrodes;
the display area comprises a second central region and two second edge regions located on both sides of the second central region, a direction from the second central region to the second edge regions intersects with a direction from the display area to the fan-out area; some of the touch electrode columns are located in the second central region, and some other touch electrode columns are located in the second edge regions;
the touch electrode columns located in the second edge regions are electrically connected to the first-type touch fan-out lines located in the first edge regions in the direction from the display area to the fan-out area, and the touch electrode columns located in the second central region are electrically connected to the second-type touch fan-out lines located in the first central region.

In at least one embodiment of the present application, the display substrate further includes:
the base;
a first conductive layer located on the base;
a gate conductive layer located on a side of the first conductive layer facing away from the base; and
a source-drain conductive layer located on a side of the gate conductive layer facing away from the base;
the second-type touch fan-out lines is arranged on the first conductive layer.

In at least one embodiment of the present application, the first conductive layer includes a light-shielding layer, the light-shielding layer is provided with a light-shielding pattern located in the display area and the second-type touch fan-out lines located in the fan-out area; the orthogonal projection of the light-shielding pattern on the base overlaps with the orthogonal projection of an active part of a transistor in the display area on the base;
a part of the source-drain conductive layer located in the display area is provided with touch signal lines, the touch signal lines are electrically connected to the touch electrodes in the display area and the touch fan-out lines in the fan-out area.

In at least one embodiment of the present application, the display substrate further includes:
the base;
a gate conductive layer located on the base;
a source-drain conductive layer located on a side of the gate conductive layer facing away from the base; and
a second conductive layer located on a side of the source-drain conductive layer facing away from the base;
the second-type touch fan-out lines are arranged on the second conductive layer.

In at least one embodiment of the present application, the second conductive layer includes a touch layer, the touch layer is provided with touch signal lines located in the display area and the second-type touch fan-out lines located in the fan-out area; the touch signal lines are electrically connected to the touch electrodes in the display area and the touch fan-out lines in the fan-out area.

In at least one embodiment of the present application, material of the second-type touch fan-out lines includes molybdenum, a thickness of the second-type touch fan-out lines is greater than 500 Å, and less than or equal to 3000 Å, and a line width of the second-type touch fan-out lines is in a range of 3 μm to 6 μm.

In at least one embodiment of the present application, a slope angle of the light-shielding layer is less than or equal to 60°.

In at least one embodiment of the present application, the minimum distance between all the touch fan-out lines and the base is substantially equal to the minimum distance between the display fan-out lines and the base;
each of the display fan-out lines and the touch fan-out lines includes a first segment and a second segment that are electrically connected, the first segment extends to a boundary between the display area and the fan-out area, and the second segment is electrically connected to a driver chip;
the first segment and the second segment of the same fan-out line are arranged in different film layers; adjacent first segments are arranged in different film layers, and adjacent second segments are located in different film layers.

In a second aspect, an embodiment of the present application provides a display panel including any display substrate described in the first aspect.

The above description is only a general overview of solutions of the present disclosure. In order to learn technical means of the present disclosure more clearly and allow the technical means to be implemented based on the disclosure of the description, and in order to make the above and other objects, features and advantages of the present disclosure more apparent and understandable, specific embodiments of the present disclosure are illustrated below.

### BRIEF DESCRIPTION OF THE DRAWINGS

In order to describe technical solutions of the embodiments of the present disclosure or the related art more clearly, the accompanying drawings used in the illustration of the embodiments or the related art will be briefly introduced. Apparently, the accompanying drawings in the following explanation illustrate merely some embodiments of the present disclosure, and those skilled in the art may obtain other accompanying drawings based on these accompanying drawings without paying any creative effort.

FIG. 1 is a schematic top view of a display substrate in the related art;

FIG. 2 is a schematic plan view of a fan-out area of the display substrate in the related art;

FIG. 3 is a schematic plan view of a fan-out area of the display substrate in the related art;

FIG. 4 is a schematic cross-sectional view of a display substrate in the related art;

FIG. 5 is a schematic cross-sectional view of a display substrate in the related art;

FIG. 6 is a schematic plan views of a fan-out area of a display substrate provided by an embodiment of the present application;

FIG. 7 is a schematic plan view of a fan-out area of a display substrate provided by an embodiment of the present application;

FIG. 8 is a schematic cross-sectional view of a display area of a display substrate provided by an embodiment of the present application;

FIGS. 9A, 9B, and FIG. 9C are cross-sectional views of a fan-out area of three types of display substrates provided by embodiments of the present application;

FIG. 10 is a cross-sectional view illustrating a connection point between a touch signal line in the display area and a touch fan-out line in the fan-out area provided by an embodiment of the present application;

FIG. 11 is a schematic plan view illustrating a distribution pattern of touch electrodes of a display substrate provided by an embodiment of the present application;

FIG. 12 is a schematic plan view of a fan-out area of a display substrate provided by an embodiment of the present application;

FIG. 13 is a schematic plan view of a fan-out area of a display substrate provided by an embodiment of the present application;

FIG. 14 is a schematic plan view illustrating a distribution pattern of touch electrodes of a display substrate provided by an embodiment of the present application; and

FIG. 15 is a schematic plan view of the fan-out area of a fifth type of display substrate provided by an embodiment of the present application.

### DETAILED DESCRIPTION

A clear and thorough description for solutions in the embodiments of the present disclosure will be given below in conjunction with the accompanying drawings in the embodiments of the present disclosure. Apparently, the described embodiments are a part of embodiments of the present disclosure, not all the embodiments. All other embodiments obtained, based on the embodiments in the present disclosure, by those skilled in the art without paying creative effort fall within the protection scope of the present disclosure.

In the embodiments of the present application, terms such as “first,” “second,” “third,” and “fourth” are used to distinguish identical or similar items with basically the same functions and roles. These terms are only for the purpose of clearly describing the technical solutions of the embodiments of the present application and should not be understood as indicating or implying relative importance or the number of the indicated technical features.

In the embodiments of the present application, terms such as “upper” and “lower” are used to describe the orientation or positional relationship based on the orientation or positional relationship shown in the accompanying drawings. These terms are only for the convenience of describing the present application and simplifying the description. They do not indicate or imply that the device or element must have a specific orientation, be constructed and operated in a specific orientation, and thus should not be understood as a limitation to the present application.

In the description of the specification, terms such as “one embodiment,” “some embodiments,” “exemplary embodiment,” “example,” “specific example,” or “some examples” are intended to indicate that the specific features, structures, materials, or characteristics related to the embodiment or example are included in at least one embodiment or example of the present application. The above terms are not necessarily referring to the same embodiment or example. Moreover, the specific features, structures, materials, or characteristics can be included in any one or more embodiments or examples in any appropriate manner.

In the embodiments of the present application, the term “multiple” means two or more, and “at least one” means one or more, unless otherwise specifically limited.

The terms “parallel,” “perpendicular,” and “identical” used in the embodiments of the present application include the strict meanings of “parallel,” “perpendicular,” and “identical,” as well as the meanings of “substantially parallel,” “substantially perpendicular,” and “substantially identical” that allow for certain tolerances. These terms take into account the measurement and the tolerances associated with the measurement of specific quantities (for example, the limitations of the measurement system), indicating an acceptable deviation range for a specific value as determined by those of ordinary skill in the art. For example, “substantially” can mean within one or more standard deviations, or within 3% or 5% of the value.

Unless otherwise required by the context, the term “comprising” used throughout the specification and claims is interpreted as open and inclusive, that is, “comprising, but not limited to.” The polygons mentioned in this specification are not strictly defined and can be approximate triangles, parallelograms, trapezoids, pentagons, hexagons, etc. There may be small deformations due to tolerances.

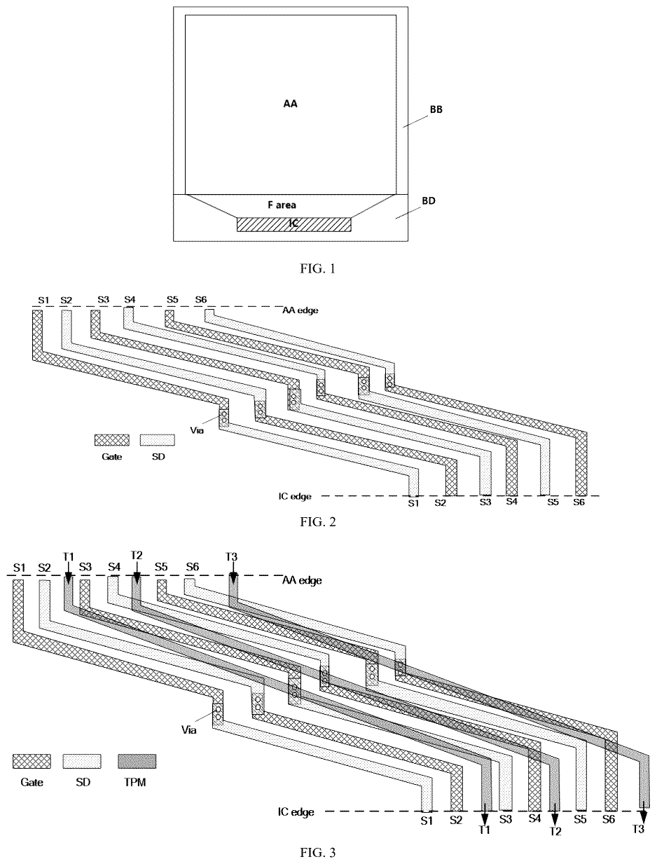

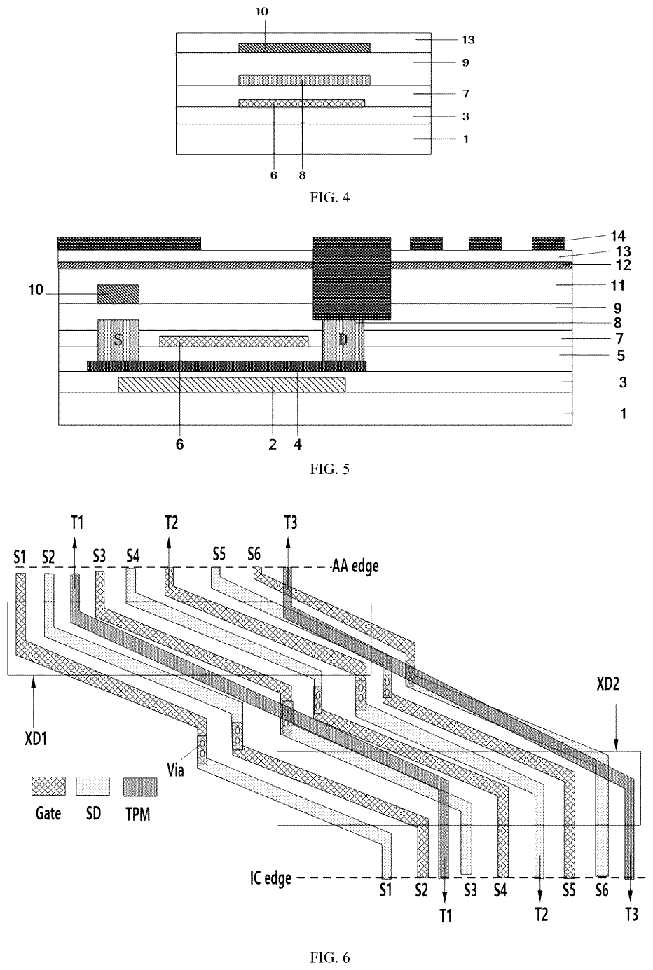

In the related art, the display area AA of a display panel with touch functionality includes multiple data signal lines (also known as Data Line or Source Line) and multiple touch signal lines (TX lines). As shown in FIG. 1, the data signal lines for transmitting display signals and the touch signal lines for transmitting touch signals usually extend to a boundary between the display area AA and the fan-out area (F area), and are electrically connected to a driver chip. To reduce the dimensions of bezels of the display panel, especially the lower bezel, as shown in FIG. 2 and FIG. 5, the display panel is designed with display fan-out lines (labeled as S1, S2, S3, S4, S5, S6) for connecting the data signal lines to the driver chip on the gate conductive layer 6 (Gate) and the source-drain conductive layer 8 (SD) in the fan-out area (F area). This dual-layer wiring approach reduces the design space for wiring. Additionally, as shown in FIG. 3 and FIG. 4, the touch conductive layer 10 is designed to be located on a side of the source-drain conductive layer 8 away from the gate conductive layer 6, and touch fan-out lines (labeled as T1, T2, T3) for connecting the touch signal lines and the driver chip are arranged on the touch conductive layer 10 in the fan-out area (F area). However, to meet the resistance requirements of the touch signal lines and the touch fan-out lines, the touch conductive layer 10 needs to be prepared using aluminum (Al) process with a lower resistivity. The Al process has capacity bottlenecks and higher costs. Moreover, since the touch conductive layer 10 is provided, an additional insulation layer 11 is required in the display panel to cover the touch conductive layer 10, which further increases the production capacity load and raises the manufacturing cost.

Additionally, in the related art, the resistance of the touch fan-out lines needs to be less than or approximately equal to 1500 Ω to ensure that the touch fan-out lines can receive sufficient signal strength. Assuming that the touch fan-out lines are made of molybdenum (Mo) with a higher resistivity to avoid the Al process, the touch fan-out lines have a narrower width (denser wiring) due to limited design space. The thickness of the Mo layer is about 3000 Å, and the sheet resistance Rs is 0.5 Ω/□. The resistance of the touch fan-out lines will be around 2500 Ω, which will result in a weak signal received by the touch fan-out lines and affect the touch performance.

In view of the above, embodiments of the present application provide a display substrate and a display panel. The display substrate includes a display area and a fan-out area located on one side of the display area. The fan-out area includes multiple display fan-out lines and multiple touch fan-out lines that are electrically connected to a driver chip respectively. A distance between at least some of the touch fan-out lines and the base of the display substrate is substantially equal to the minimum distance between the display fan-out lines and the base. In the display substrate provided by the embodiments of the present application, in a direction perpendicular to the plane where the base of the display substrate is located, the distance between at least some of the touch fan-out lines and the base is substantially equal to the distance between the display fan-out lines and the base, so that at least some of the touch fan-out lines are arranged on the same layer as the display fan-out lines. This releases the design space for the touch fan-out lines. In the actual manufacturing process, at least some of the touch fan-out lines can be prepared in the same manufacturing process as the display fan-out lines. This approach not only ensures narrow bezels and signal transmission performance, but also reduces production capacity load, shortens manufacturing cycles, and lowers material costs as well as process costs.

The display substrate and display panel provided by the embodiments of the present application is described in details with reference to the accompanying drawings.

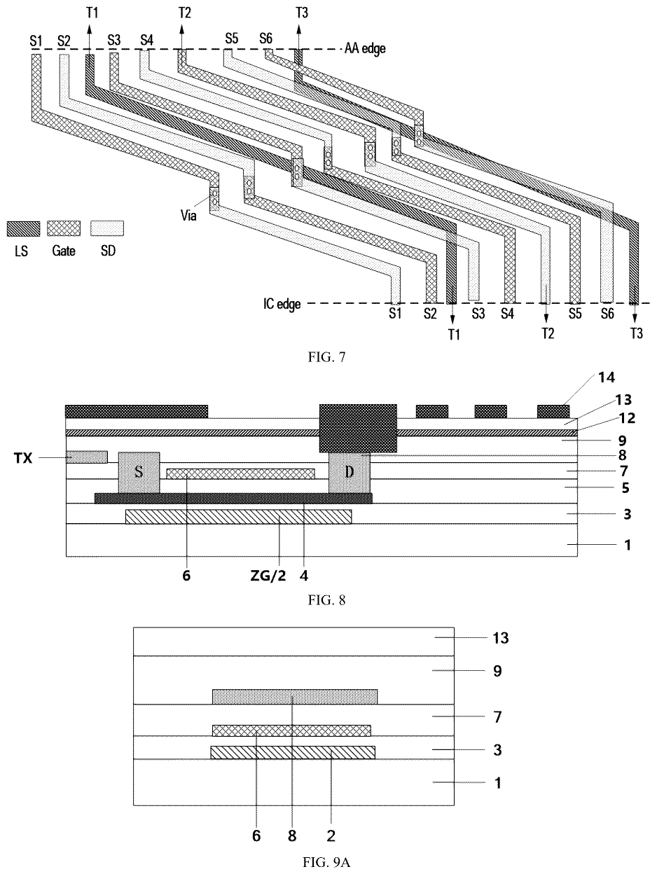

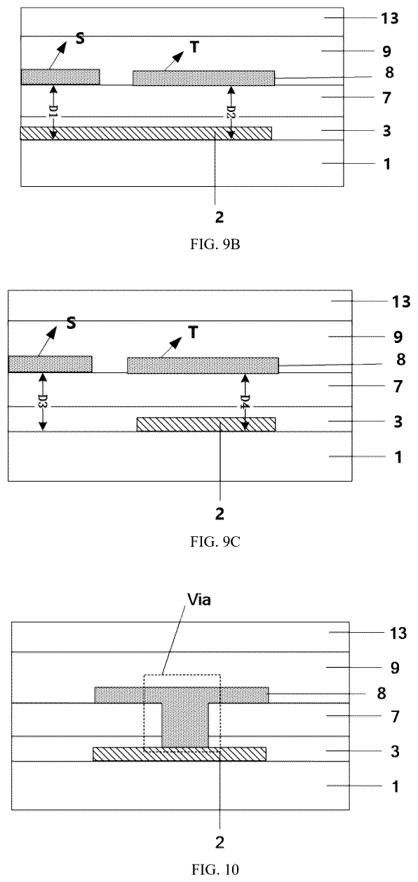

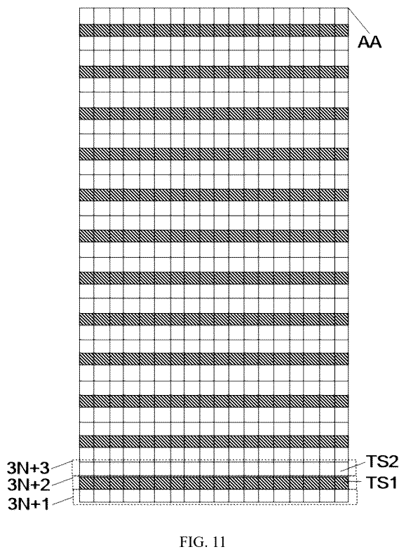

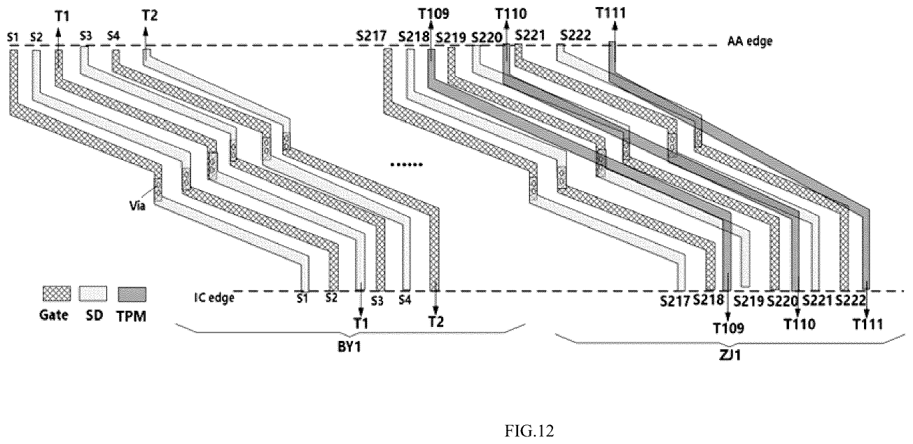

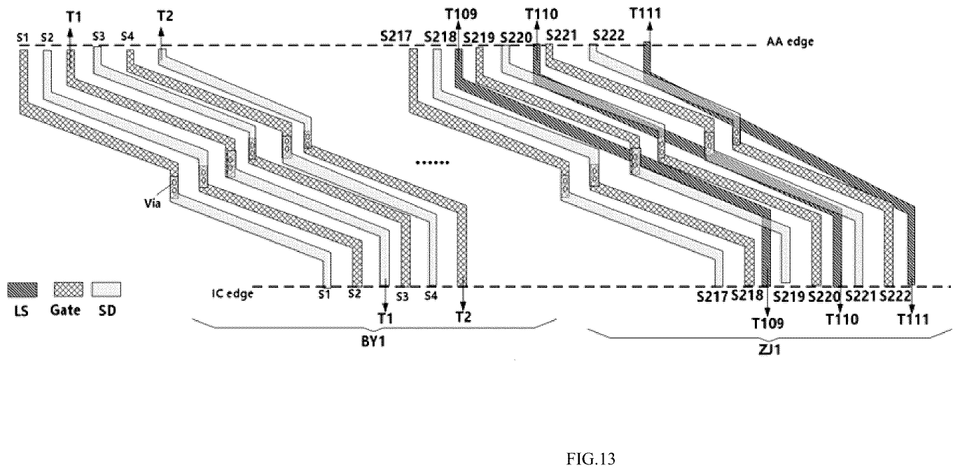

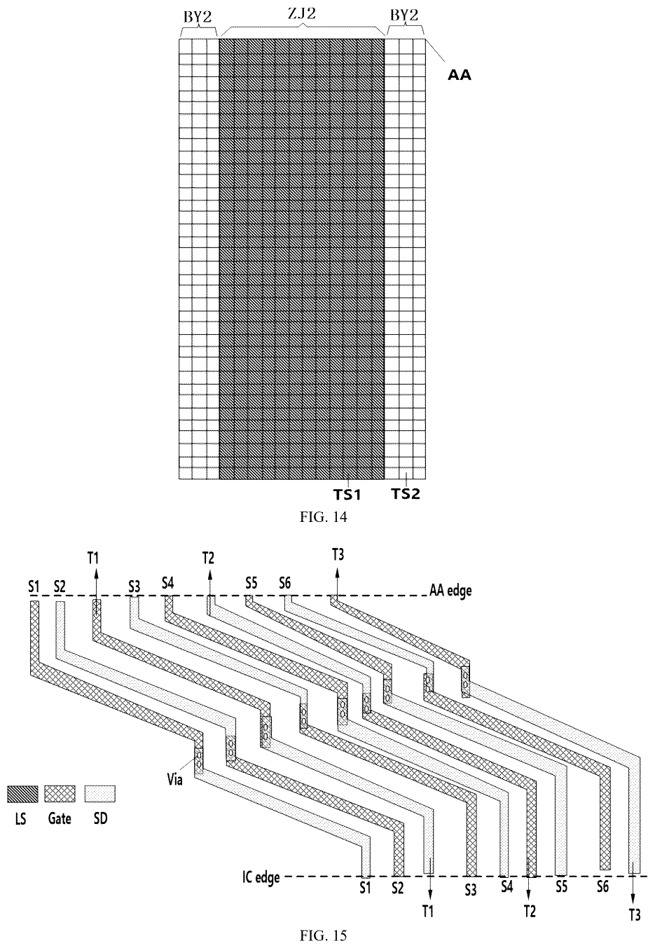

FIG. 6, FIG. 7, FIG. 12, and FIG. 13 are schematic plan views of the fan-out area (F area) of the display substrate. FIG. 8 is a schematic cross-sectional view of a display substrate at the display area AA. FIG. 9A and FIG. 9B are schematic cross-sectional views of two types of display substrates at the fan-out area (F area). FIG. 10 is a schematic cross-sectional view of a connection point between the touch signal line TX in the display area AA and the touch fan-out line T in the fan-out area (F area). FIG. 11 and FIG. 14 are schematic plan views illustrating the distribution of touch electrodes in two types of display substrates provided by the embodiments of the present application. It should be noted that FIG. 6, FIG. 7, FIG. 12, and FIG. 13 only show a part of the display substrate rather than the entire display substrate. FIG. 8, FIG. 9A, and FIG. 9B merely show a part of the display substrate rather than the entire layer structure of the display substrate. The unshown layer structure can refer to the related technology.

At least one embodiment of the present application provides a display substrate, which includes a display area AA and a fan-out area F area located on one side of the display area AA.

As shown in FIG. 6, FIG. 7, FIG. 12, and FIG. 13, the fan-out area (F area) includes multiple display fan-out lines S and multiple touch fan-out lines T, and the display fan-out lines S and the touch fan-out lines T are electrically connected to the driver chip IC respectively. As shown in FIG. 9B, in a direction perpendicular to a plane where a base 1 of the display substrate is located, a distance D2 between at least some of the touch fan-out lines T and the base 1 of the display substrate is substantially equal to a distance D1 between the display fan-out lines S and the base 1.

In an exemplary embodiment, the above display substrate can be used to prepare liquid crystal display (LCD) panels. For example, the liquid crystal display panels may include a TN (Twisted Nematic) LCD panel, a VA (Vertical Alignment) LCD panel, an IPS (In Plane Switching) LCD panel, and an ADS (Advanced Super Dimension Switch) LCD panel.

The liquid crystal display panel can include the display substrate described above and a color filter substrate, with a liquid crystal layer (LC) located between the display substrate and the color filter substrate. The display substrate and the color filter substrate each include a base, and the term “base” mentioned throughout the embodiments of the present application refers to the base in the display substrate. The specific structures and components included in the display substrate and the color filter substrate of the above display panel are not limited here and can be determined according to the product design.

The specific material of the base of the display substrate is not limited here. For example, the base may be made of any one of materials such as silicon, glass, quartz, PET, or plastic.

In some embodiments of the present application, the display panel includes a display area AA and a peripheral area BB surrounding the display area AA. The peripheral area BB includes a fan-out area F area and a bonding area BD. The fan-out area (F area) and the bonding area BD are both located on one side of the display area AA, and the fan-out area (F area) is located between the display area AA and the bonding area BD. The driver chip is bonded in the bonding area BD.

In an exemplary embodiment, data lines DL extending in a column direction and gate lines GL extending in a row direction are provided in the display area AA of the display substrate.

For example, the gate line GL can include a straight segment or a bent structure formed by multiple straight segments. The specific design of the gate line GL can be determined according to the actual design.

For example, the data line DL can include a straight segment or a bent structure formed by multiple straight segments. The specific design of the data line DL can be determined according to the actual design.

The specific materials of the gate line GL and data line DL are not limited here.

For example, the material of the data line DL can include aluminum (Al). For example, the data line DL includes a single-layer structure of aluminum, or a laminated structure of molybdenum/aluminum/molybdenum (Mo/Al/Mo). Alternatively, the data line DL includes a laminated structure of titanium/aluminum/titanium (Ti/Al/Ti).

For example, the material of the gate line GL can include copper. For example, a laminated structure of MoNb/Cu/MoNb is formed by sputtering. MoNb is located on the side close to the base, with a thickness of about 300 Å, mainly used to improve the adhesion between the film layers. The middle layer of the laminated structure is made of Cu, which is the material for an electrical signal transmission channel. The material on the side away from the base 1 is MoNb, with a thickness of about 200 Å, which can be used to protect the middle layer and prevent the surface of the middle layer with a low resistance from being exposed and oxidized. Since the thickness of a single sputtering is generally not more than 1 μm, multiple sputtering processes are required to form a gate line GL with a thickness exceeding 1 μm. Moreover, the gate line GL can also be formed through electroplating. Specifically, MoNiTi is used to form a seed layer first, so as to increase the nucleation density of metal grains in the subsequent electroplating process. Then, low-resistance copper is formed through electroplating, followed by the fabrication of an anti-oxidation layer. The anti-oxidation layer can be made of MoNiTi.

As an example, the material of the data line DL can be the same as that of the gate line GL.

The display fan-out lines S in the fan-out area (F area) are electrically connected to the data lines DL extending in the column direction.

In some embodiments, at least some of the display fan-out lines S can be arranged on the same layer as the data lines DL extending in the column direction.

In some other embodiments, at least some of the display fan-out lines S can be arranged on the same layer as the gate lines GL extending in the row direction.

In some other embodiments, some of the display fan-out lines S can be arranged on the same layer as the data lines DL extending in the column direction, and some of the display fan-out lines S can be arranged on the same layer as the gate lines GL extending in the row direction.

It should be noted that FIG. 9B and FIG. 9C are drawn with partial segments of some of the touch fan-out lines T located on the source-drain conductive layer 8 (SD) and partial segments of the display fan-out lines S located on the source-drain conductive layer 8 (SD) as examples, which does not represent a limitation on the film layer where some of the touch fan-out lines T and the display fan-out lines S are located.

In an exemplary embodiment, as shown in FIG. 9B, at least some of the touch fan-out lines T can be arranged on the same layer as the display fan-out lines S.

As an example, when the display fan-out lines S and the data lines DL extending in the column direction are arranged on the same layer, at least some of the touch fan-out lines T (referred to as a first-type touch fan-out lines T hereinafter) can be arranged on the same layer as the data lines DL, where the data lines DL are arranged on the source-drain conductive layer 8 (SD).

As another example, when the display fan-out lines S and the gate lines GL extending in the row direction are arranged on the same layer as, at least some of the touch fan-out lines T (referred to as the first-type touch fan-out lines T hereinafter) can be arranged on the same layer as the gate lines GL, where the gate lines GL are arranged on the gate conductive layer 6.

As another example, when some of the display fan-out lines S and the data lines DL extending in the column direction are arranged on the same layer and some of the display fan-out lines S and the gate lines GL extending in the row direction are arranged on the same layer, some of the touch fan-out lines T (referred to as the first-type touch fan-out lines T hereinafter) can be arranged on the same layer as the data lines DL, and some of the touch fan-out lines T (referred to as the first-type touch fan-out lines T hereinafter) can be arranged on the same layer as the gate lines GL.

It should be noted that in this specification, “being arranged on the same layer” means that at least partial regions of two structures can be arranged in the same film layer. When two structures are arranged in the same film layer, they can be formed through the same manufacturing process with the same material. In an exemplary embodiment, the display area AA of the display substrate includes multiple touch electrodes arranged in an array (for example, touch electrodes in a shape of blocks) Each of the touch electrodes is electrically connected to the touch fan-out line T in the fan-out area (F area) through the touch signal line TX.

In some embodiments, the touch electrodes can be arranged in the common electrode layer.

In some embodiments, as shown in FIG. 8, the touch signal line TX and the data line DL can be arranged on the same layer, and the data line DL is located in the source-drain conductive layer 8.

In some embodiments, the touch signal line TX and the gate line GL can be arranged on the same layer, and the gate line GL is located in the gate conductive layer 6.

The type of the driver chip IC is not limited here.

For example, the driver chip can be a SRIC (Source/Read-out IC) driver chip. Alternatively, the driver chip can be a TDDIC (Touch with Display Driver IC) driver chip.

The situation that in the direction perpendicular to the plane where the base 1 of the display substrate is located, the distance D2 between at least some of the touch fan-out lines T and the base 1 of the display substrate is substantially equal to the distance D1 between the display fan-out lines S and the base 1, can be achieved through the following manners but not limited to these manners.

In a first manner, in the direction perpendicular to the plane where the base 1 of the display substrate is located, the distance D2 between some of the touch fan-out lines T and the base 1 of the display substrate is substantially equal to the distance D1 between the display fan-out lines S and the base 1.

For example, for multiple touch fan-out lines T, in the direction perpendicular to the plane where the base 1 of the display substrate is located, the distance D2 between these touch fan-out lines and the base 1 is substantially equal to the distance D1 between the display fan-out lines S and the base.

For example, for some segments of the same touch fan-out line T, in the direction perpendicular to the plane where the base 1 of the display substrate is located, the distance D2 between the touch fan-out line T and the base 1 is substantially equal to the distance D1 between the display fan-out lines S and the base 1.

In a second manner, in the direction perpendicular to the plane where the base 1 of the display substrate is located, the distance D2 between all the touch fan-out lines T and the base 1 of the display substrate is substantially equal to the distance D1 between the display fan-out lines S and the base 1.

It should be noted that in the embodiments of the present application, in the expression “in the direction perpendicular to the plane where the base 1 of the display substrate is located, the distance D2 between at least some of the touch fan-out lines T and the base 1 of the display substrate is substantially equal to the distance D1 between the display fan-out lines S and the base 1”:

The distance D1 refers to an average value of the distances, along the direction perpendicular to the plane where the base 1 of the display substrate is located, between different line segments of the same touch fan-out line T and the base 1. Alternatively, the distance D1 refers to the average value of the distances, along the direction perpendicular to the plane where the base 1 of the display substrate is located, between multiple touch fan-out lines T and the base 1 of the display substrate.

The distance D2 refers to the average value of distances, along the direction perpendicular to the plane where the base 1 of the display substrate is located, between different line segments of the same display fan-out line S and the base 1. Alternatively, the distance D2 refers to the average value of distances, along the direction perpendicular to the plane where the base 1 of the display substrate is located, between multiple display fan-out lines S and the base 1.

In practical applications, if different structures are provided under the display fan-out lines S and a part of the touch fan-out lines T (the first-type touch fan-out lines T hereinafter), for example, as shown in FIG. 9C, a conductive pattern (including but not limited to signal lines or connection lines) located in the light-shielding layer 2 being provided under some segments of the touch fan-out line T, and no conductive pattern being provided under some segments of the display fan-out line S, then in the direction perpendicular to the plane where the base 1 is located, the distance D4 between some segments of the touch fan-out line T and the base 1 is greater than the distance D3 between some segments of the display fan-out line S and the base 1.

In other regions, a conductive pattern (including but not limited to signal lines or connection lines) located in the light-shielding layer 2 is provided under some segments of the display fan-out line S, and no conductive pattern is provided under some segments of the touch fan-out line T. In this case, in the direction perpendicular to the plane where the base 1 is located, the distance D4 between some segments of the touch fan-out line T and the base 1 is less than the distance D3 between some segments of the display fan-out line S and the base 1.

For the case where a conductive pattern (including but not limited to signal lines or connection lines) located in the light-shielding layer 2 being provided under some segments of the touch fan-out line T, and no conductive pattern being provided under some segments of the display fan-out line S, the absolute value of the difference between the distance D4 and the distance D3 is less than or equal to the thickness of the light-shielding layer 2. The introduction related to the thickness of the light-shielding layer 2 can refer to the explanation in the following text, which will not be repeated here.

In the embodiments of the present application, “substantially equal” means being within one or more standard deviations, or within 3% or 5% of the average value.

According to the display substrate provided by the embodiments of the present application, in the direction perpendicular to the plane where the base 1 of the display substrate is located, the distance D2 between at least some of the touch fan-out lines T and the base 1 of the display substrate is substantially equal to the distance D1 between the display fan-out lines S and the base 1. Accordingly, at least some of the touch fan-out lines T and the display fan-out lines S are arranged on the same layer. This releases the design space for the touch fan-out lines. In the actual manufacturing process, at least some of the touch fan-out lines T and the display fan-out lines S can be prepared through the same manufacturing process. This approach not only ensures narrow bezels and the resistance requirements and transmission performance of the signal lines, but also reduces production capacity load, shortens manufacturing cycles, and lowers material costs as well as process costs.

In at least one embodiment of the present application, as shown in FIGS. 6, 7, 12, and 13, the touch fan-out lines T are divided into the first type and the second type. The orthogonal projections of the display fan-out lines S and the orthogonal projections of the first-type touch fan-out lines T on the base do not overlap with each other, while the orthogonal projections of the display fan-out lines S and the orthogonal projections of the second-type touch fan-out lines T on the base overlap with each other. It should be noted that, in order to avoid the unclearness caused by excessive labels in the accompanying drawings, the first-type touch fan-out lines T and the second-type touch fan-out lines T can be distinguished according to the relationship between their projections and the projections of the display fan-out lines S.

In an exemplary embodiment, the phrase that the orthogonal projections of the display fan-out lines S and the orthogonal projections of the second-type touch fan-out lines T on the base overlap with each other means that the orthogonal projections of the display fan-out lines S on the base at least partially overlaps with the orthogonal projections of the second-type touch fan-out lines T on the base.

In an exemplary embodiment, the display fan-out lines S and the second-type touch fan-out lines T are located in different film layers.

In an exemplary embodiment, at least some of the display fan-out lines S and some of the first-type touch fan-out lines T are located in the same film layer.

As an example, the display fan-out lines S are arranged in the gate conductive layer, and at least some of the first-type touch fan-out lines T are also arranged in the gate conductive layer.

As another example, the display fan-out lines S are arranged in the source-drain conductive layer, and at least some of the first-type touch fan-out lines T are arranged in the source-drain conductive layer.

As another example, some display fan-out lines S are arranged in the gate conductive layer, and some display fan-out lines S are arranged in the source-drain conductive layer; some of the first-type touch fan-out lines T are also arranged in the gate conductive layer, and some of the first-type touch fan-out lines T are also arranged in the source-drain conductive layer.

As an example, for a single display fan-out line S, some segments thereof are arranged in the gate conductive layer, and some other segments thereof are arranged in the source-drain conductive layer. For a single touch fan-out line T of the first type, some segments thereof are also arranged in the gate conductive layer, and some other segments thereof are also arranged in the source-drain conductive layer.

In at least one embodiment of the present application, as shown in FIG. 9B, the minimum distance D2 between the first-type touch fan-out lines T and the base 1 is substantially equal to the minimum distance D1 between the display fan-out lines S and the base 1. As shown in FIG. 7, the minimum distance between the second-type touch fan-out lines T (for example, touch fan-out lines T arranged in the film layer LS) and the base 1 is less than the minimum distance between the display fan-out lines S and the base 1.

In FIG. 7, the following conductive layers are sequentially arranged on the base in the direction away from the base: the light-shielding layer LS, the gate conductive layer Gate, and the source-drain conductive layer SD. When the display fan-out lines S are arranged on the gate conductive layer Gate and/or the source-drain conductive layer SD, and the second-type touch fan-out lines T are arranged on the light-shielding layer LS, the minimum distance between the second-type touch fan-out lines T (for example, touch fan-out lines T arranged on the light-shielding layer LS) and the base 1 is less than the minimum distance between the display fan-out lines S and the base 1.

In at least one embodiment of the present application, as shown in FIG. 9B, the minimum distance D2 between the first-type touch fan-out lines T and the base 1 is substantially equal to the minimum distance D1 between the display fan-out lines S and the base 1. As shown in FIG. 6, the minimum distance between the second-type touch fan-out lines T (for example, touch fan-out lines T arranged in the touch conductive layer TPM) and the base 1 is greater than the minimum distance between the display fan-out lines S and the base 1.

In FIG. 6, the following conductive layers are sequentially arranged on the base in the direction away from the base: the gate conductive layer Gate, the source-drain conductive layer SD, and the touch conductive layer TPM. When the display fan-out lines S are arranged on the gate conductive layer Gate and/or the source-drain conductive layer SD, and the second-type touch fan-out lines T are arranged on the touch conductive layer TPM, the minimum distance between the second-type touch fan-out lines T (for example, touch fan-out lines T arranged in the touch conductive layer TPM) and the base 1 is greater than the minimum distance between the display fan-out lines S and the base 1.

In at least one embodiment of the present application, as shown in FIGS. 6 and 7, the first-type touch fan-out lines T (for example, being arranged on the gate conductive layer Gate and/or the source-drain conductive layer SD) and the second-type touch fan-out lines T (for example, being arranged on the touch conductive layer TPM in FIG. 6, or being arranged on the light-shielding layer LS in FIG. 7) are located in different film layers. At least some of the first-type touch fan-out lines T are located in the same film layer, and the second-type touch fan-out lines T are located in the same film layer.

In an exemplary embodiment, the display fan-out lines S are arranged in the gate conductive layer 6 and/or the source-drain conductive layer 8, and the first-type touch fan-out lines T are arranged in the gate conductive layer 6 and/or the source-drain conductive layer 8. The minimum distance between the first-type touch fan-out lines T and the base 1 is substantially equal to the minimum distance between the display fan-out lines S and the base 1.

In a first case, the display fan-out lines S and the first-type touch fan-out lines T are both arranged in the gate conductive layer 6, the minimum distance between the first-type touch fan-out lines T and the base 1 is substantially equal to the minimum distance between the display fan-out lines S and the base 1. In this case, the minimum distance refers to the distance in the direction perpendicular to the base 1.

In a second case, the display fan-out lines S and the first-type touch fan-out lines T are both arranged in the source-drain conductive layer 8. The minimum distance between the first-type touch fan-out lines T and the base 1 is substantially equal to the minimum distance between the display fan-out lines S and the base 1. In this case, the minimum distance refers to the distance in the direction perpendicular to the base 1.

In a third case, as shown in FIG. 6 or FIG. 7, some display fan-out lines S are arranged in the gate conductive layer 6, and some display fan-out lines S are arranged in the source-drain conductive layer 8; some of the first-type touch fan-out lines T are arranged in the gate conductive layer 6, and some of the first-type touch fan-out lines T are arranged in the source-drain conductive layer 8; the minimum distance between the first-type touch fan-out lines T and the base 1 is substantially equal to the minimum distance between the display fan-out lines S and the base 1. In this case, the minimum distance between the first-type touch fan-out lines T and the base 1 refers to the distance in the direction perpendicular to the base 1 between some of the first-type touch fan-out lines T arranged in the gate conductive layer 6 (the film layer closer to the base 1) and the base 1. The minimum distance between the display fan-out lines S and the base 1 refers to the distance in the direction perpendicular to the base 1 between some of the display fan-out lines S arranged in the gate conductive layer 6 (the film layer closer to the base 1) and the base 1.

In an exemplary embodiment, the second-type touch fan-out lines T can be located on a side of the source-drain conductive layer 8 facing away from the base 1 and on a side of the gate conductive layer 6 facing away from the base 1. In this case, the minimum distance between the second-type touch fan-out lines T and the base 1 (the distance in the direction perpendicular to the plane where the base 1 is located) is greater than the minimum distance between the display fan-out lines S and the base 1 (that is, the distance in the direction perpendicular to the plane where the base 1 is located).

In an exemplary embodiment, the second-type touch fan-out lines T can be located on a side of the source-drain conductive layer 8 close to the base 1 and on a side of the gate conductive layer 6 close to the base 1. In this case, the minimum distance between the second-type touch fan-out lines T and the base 1 (the distance in the direction perpendicular to the plane where the base 1 is located) is less than the minimum distance between the display fan-out lines S and the base 1 (that is, the distance in the direction perpendicular to the plane where the base 1 is located).

It should be noted that the above “minimum distance” refers to an average value of minimum distances between different segments of the same fan-out line and the base.

In at least one embodiment of the present application, as shown in FIGS. 6, 7, 12, and 13, each of the display fan-out lines S and the first-type touch fan-out lines T includes a first segment XD1 and a second segment XD2 that are electrically connected. The first segment XD1 extends to the boundary between the display area AA and the fan-out area (F area), and the second segment is electrically connected to the driver chip IC.

It should be noted that, in order to avoid the unclearness caused by excessive labels in the accompanying drawings, the first segment XD1 and the second segment XD2 are labeled only in FIG. 6. The first segment XD1 and the second segment XD2 are also included in FIGS. 7, 12, and 13, which can refer to the labels in FIG. 6.

The first segment XD1 and the second segment XD2 of the same fan-out line are located in different film layers. Two adjacent first segments XD1 are located in different film layers, and two adjacent second segments XD2 are located in different film layers.

In an exemplary embodiment, as shown in FIG. 6, among the touch fan-out lines T1, T2, and T3, the touch fan-out line T2 is the first-type touch fan-out line T, while the touch fan-out lines T1 and T3 are the second-type touch fan-out lines T.

Specifically, each of the display fan-out lines S (e.g., S1, S2, S3, S4, S5, S6) and the first-type touch fan-out lines T (e.g., T2) includes a first segment XD1 and a second segment XD2 that are electrically connected. The first segment XD1 and the second segment XD2 of the same fan-out line are located in different film layers. Adjacent first segments XD1 are located in different film layers, and adjacent second segments XD2 are located in different film layers.

The term “adjacent first segments XD1” refers to two first segments between which no other first segment XD1 exists. The meaning of “adjacent second segments XD2” is analogous and will not be repeated.

In an exemplary embodiment, as shown in FIG. 6, for the same fan-out line, either of the first segment XD1 and the second segment XD2 is located in the source-drain conductive layer SD, and the other is located in the gate conductive layer (Gate). For two adjacent first segments XD1, one of them is located in the source-drain conductive layer SD, and the other one is located in the gate conductive layer (Gate). For two adjacent second segments XD2, one of them is located in the source-drain conductive layer SD, and the other one is located in the gate conductive layer (Gate).

In an exemplary embodiment, the length of the first segment XD1 is substantially equal to the length of the second segment XD2.

The phrase “the length of the first segment XD1 is substantially equal to the length of the second segment XD2” includes following situations: the length of the first segment XD1 is equal to the length of the second segment XD2; or, the difference between the lengths of the first segment (XD1) and the second segment (XD2) is less than or equal to 5% of a central value, where the central value is the average length of XD1 and XD2.

In the embodiments of the present application, by configuring the lengths of the first segment XD1 and the second segment XD2 to be approximately equal, the resistance variation among all fan-out lines with the first segment XD1 and the second segment XD2 can be minimized, allowing the resistance values of the fan-out lines to be consistent as soon as possible. This approach helps prevent signal transmission loss discrepancies between different fan-out lines caused by resistance variations, thereby improving signal transmission uniformity and ultimately enhancing the performance of the display substrate.

In at least one embodiment of the present application, the number of the first-type touch fan-out lines T is less than the number of the second-type touch fan-out lines T.

In at least one embodiment of the present application, the number of the first-type touch fan-out lines T is one-Mth (1/M) of the total number of touch fan-out lines T, where M is a positive integer equal to or greater than 2.

Among the touch fan-out lines, every M lines form a group, with one of the touch fan-out lines being the first-type touch fan-out line T.

In at least one embodiment of the present application, the number of first-type touch fan-out lines T is one third of the total number of all touch fan-out lines T. All touch fan-out lines T are divided in a way that the (3N+1)th, (3N+2)th, and (3N+3)th touch fan-out lines T form one group.

Among them, the (3N+1)th and (3N+3)th touch fan-out lines T are the second-type touch fan-out lines, while the (3N+2)th touch fan-out line T is the first-type touch fan-out line. The orthographic projections of the (3N+1)th and (3N+3)th touch fan-out lines T on the base overlap with the orthographic projection of the display fan-out line S on the base 1, respectively, while the orthographic projection of the (3N+2)th touch fan-out line T on the base 1 and the orthographic projection of the display fan-out line S on the base 1 do not overlap with each other. Here, N is an integer.

For example, as shown in FIGS. 6 and 7, when N is 0, the 1st touch fan-out line T1 and the 3rd touch fan-out line T3 are the second-type touch fan-out lines, and the 2nd touch fan-out line T2 is the first-type touch fan-out line. The orthogonal projections of the 1st touch fan-out line T1 and the 3rd touch fan-out line T3 on the base overlap with the orthogonal projections of the display fan-out lines S on the base 1, while the orthogonal projection of the 2nd touch fan-out line T2 on the base does not overlap with the orthogonal projections of the display fan-out lines S on the base 1.

When N is 1, the 4th touch fan-out line T4 and the 6th touch fan-out line T6 are the second-type touch fan-out lines, and the 5th touch fan-out line T5 is the first-type touch fan-out line. The orthogonal projections of the 4th touch fan-out line T4 and the 6th touch fan-out line T6 on the base overlap with the orthogonal projections of the display fan-out lines S on the base 1, while the orthogonal projection of the 5th touch fan-out line T5 on the base does not overlap with the orthogonal projections of the display fan-out lines S on the base 1.

The cases where N is other integers are similar to the above situations, and will not be listed one by one here.

In an exemplary embodiment, the number of the first-type touch fan-out lines T is one third of the total number of all the touch fan-out lines T, for example, 216 first-type touch fan-out lines T, and 432 second-type touch fan-out lines. The first-type touch fan-out lines adopt the dual-layer wiring method same as that adopted by the display fan-out lines S, this greatly releases the wiring design space of the film layer where the second-type touch fan-out lines are located. Therefore, the second-type touch fan-out lines can use Mo material with a higher resistance, and the line width of the second-type touch fan-out lines is increased to reduce the resistance of the second-type touch fan-out lines. In this way, under the premise of meeting the resistance requirements of the touch fan-out lines T, the use of Al process with production capacity bottleneck is avoided, thereby improving production capacity and reducing production costs.

In at least one embodiment of the present application, as shown in FIG. 11, the display area AA includes multiple touch electrode rows arranged in an array. One touch electrode row includes multiple touch electrodes TS (TS1 or TS2).

All the touch electrode rows are divided in a way that the (3N+1)th, (3N+2)th, and (3N+3)th touch electrode rows form one group. In each group, there is one touch electrode row where all touch electrodes are electrically connected to the first-type touch fan-out lines T.

In an exemplary embodiment, all touch electrodes in the same touch electrode row are connected to the same type of touch fan-out lines T.

For example, in FIG. 11, touch electrodes electrically connected to the first-type touch fan-out lines T are labeled as TS1, and touch electrodes electrically connected to the second-type touch fan-out line T are labeled as TS2. It can be seen that in the display area AA, the touch electrode rows connected to the first-type touch fan-out lines T are almost evenly distributed.

In the display substrate provided by the embodiments of the present application, by configuring one touch fan-out line T in each group of touch fan-out lines T as the first-type touch fan-out line (that is, one touch fan-out line T in each group can include an electrically connected first segment XD1 and second segment XD2, similar to the display fan-out lines S), the first-type touch fan-out lines T can be distributed relatively uniformly among all touch fan-out lines T. Furthermore, by grouping the (3N+1)th, (3N+2)th, and (3N+3)th rows of touch electrodes in all touch electrode rows, and ensuring that all touch electrodes in one touch electrode row within the same group are electrically connected to the first-type touch fan-out lines T, the touch electrode rows connected to the first-type touch fan-out lines T can be further distributed almost uniformly across the display area AA. This configuration ensures that all touch electrodes in the same row are connected to the same type of touch fan-out lines T, thereby minimizing resistance variations among the touch fan-out lines T connected to the touch electrodes in the same row. As a result, the consistency of touch signals received by the touch electrodes in the same row is improved, leading to enhanced touch performance.

In at least one embodiment of the present application, as shown in FIG. 12 and FIG. 13, the number of the first-type touch fan-out lines is one-Mth of the total number of all touch fan-out lines, where M is a positive integer equal to or greater than 2.

Multiple touch fan-out lines arranged in a direction intersecting with the direction from the display area AA to the fan-out area (F area) form a touch fan-out line group. In some of the touch fan-out line groups, all the touch fan-out lines T are of the first type, while in other touch fan-out line groups, all the touch fan-out lines T are of the second type.

Here, the direction intersecting with the direction from the display area AA to the fan-out area (F area) means it is different from the direction from the display area AA to the fan-out area (F area); in other words, it is not overlapping (not parallel) with the direction from the display area AA to the fan-out area (F area).

In an exemplary embodiment, in the touch fan-out line groups near the edge of the display substrate, all the touch fan-out lines T are of the first type, while in the touch fan-out line groups near the central region of the fan-out area (F area) of the display substrate, all the touch fan-out lines T are of the second type.

In an exemplary embodiment, in the touch fan-out line groups near the edge of the display substrate, all the touch fan-out lines T are of the second type, while in the touch fan-out line groups near the central region of the fan-out area (F area) of the display substrate, all the touch fan-out lines T are of the first type.

In at least one embodiment of the present application, as shown in FIG. 12 and FIG. 13, the fan-out area (F area) includes a first central region ZJ1 and two first edge regions BY1 located on both sides of the first central region ZJ1. The direction from the first central region ZJI to the first edge regions BY1 intersects with the direction from the display area AA to the fan-out area (F area). It should be noted that FIG. 12 and FIG. 13 only show the arrangement of fan-out lines in a partial area of the fan-out area (F area).

Some of the first-type touch fan-out lines are located in one of the first edge regions BY1, and some of the first-type touch fan-out lines are located in the other first edge region BY1. The second-type touch fan-out lines are located in the first central region ZJ1.

It should be noted that the specific sizes of the first central region ZJI and the two first edge regions BY1 located on both sides of the first central region ZJI are not limited here, which can be designed according to the number of wirings.

For example, the sizes of the two first edge regions BY1 can be set to be the same, ensuring an equal number of first-type touch fan-out lines arranged in each region. This approach simplifies the design and reduces costs.

For example, as shown in FIG. 12, the first-type touch fan-out lines include touch fan-out lines T1 and T2, and the second-type touch fan-out lines include touch fan-out lines T109, T110, and T111. The first-type touch fan-out lines are located at the first edge region BY1, and the second-type touch fan-out lines are located at the first central region ZJ1. FIG. 12 only shows the fan-out line distribution in one first edge region BY1. The other first edge region BY1 is located on the right side of the first central region ZJ1, with a fan-out line distribution similar to that of the left first edge region BY1. In FIG. 12, the film layer where the second-type touch fan-out lines T is located (for example, the TPM layer) is on a side of the film layer where the first-type touch fan-out lines are located, facing away from the base 1.

For example, as shown in FIG. 13, the first-type touch fan-out lines include touch fan-out lines T1 and T2, and the second-type touch fan-out lines include touch fan-out lines T109, T110, and T111. The first-type touch fan-out lines are located at the first edge region BY1, and the second-type touch fan-out lines are located at the first central region ZJ1. FIG. 13 only shows the fan-out line distribution in one first edge region BY1. The other first edge region BY1 is located on the right side of the first central region ZJ1, with a fan-out line distribution similar to that of the left first edge region BY1. In FIG. 13, the film layer where the second-type touch fan-out lines are located (for example, the LS layer) is between the film layer where the first-type touch fan-out lines are located and the base 1.

In the embodiments of the present application, the fan-out area (F area) is configured to include a first central region ZJI and two first edge regions BY1 located on both sides of the first central region ZJ1. Some of the first-type touch fan-out lines are located in one of the first edge regions BY1, while the remaining first-type touch fan-out lines are located in the other first edge region BY1. The second-type touch fan-out lines are located in the first central region ZJ1. Thus, since the number of the second-type touch fan-out lines is greater than that of the first-type touch fan-out lines, it enables as many fan-out lines as possible to be positioned in the relatively central area of the fan-out area (F area). This can significantly free up space in the edge regions of the fan-out area (F area). Consequently, it is conducive to further reducing the bezel of the display panel and facilitates the production of narrow-bezel display products.

In at least one embodiment of the present application, as shown in FIG. 14, the display area AA includes multiple touch electrode columns arranged in an array. Each touch electrode column includes multiple touch electrodes.

The display area AA includes a second central region ZJ2 and two second edge regions BY2 located on both sides of the second central region ZJ2. The direction from the second central region ZJ2 to the second edge regions BY2 intersects with the direction from the display area AA to the fan-out area (F area). Some touch electrode columns are located in the second central region ZJ2, and some touch electrode columns are located in the second edge regions BY2.

The touch electrode columns located in the second edge regions BY2 are electrically connected to the first-type touch fan-out lines located in the first edge regions BY1 in the direction from the display area AA to the fan-out area (F area). The touch electrode columns located in the second central region ZJ2 are electrically connected to the second-type touch fan-out lines located in the first central region ZJ1.

For example, as shown in FIG. 13 and FIG. 14, or as shown in FIG. 12 and FIG. 14, the touch electrode columns in the display area AA located in the left second edge region BY2 are electrically connected to the first-type touch fan-out lines located in the left first edge region BY1 in the fan-out area (F area). The touch electrode columns in the display area AA located in the right second edge region BY2 are electrically connected to the first-type touch fan-out lines located in the right first edge region BY1 in the fan-out area (F area).

It should be noted that the specific sizes of the second central region ZJ2 and the two second edge regions BY2 located on both sides of the second central region ZJ2 are not limited here, which can be designed according to the number of wirings.

For example, the two second edge regions BY2 can be configured with identical sizes to ensure an equal number of touch electrode columns are arranged in each region. This approach simplifies the design and reduces costs.

In at least one embodiment of the present application, as shown in FIG. 9A, the display substrate also includes:
a base 1;
a first conductive layer located on the base 1;
a gate conductive layer 6 located on a side of the first conductive layer facing away from the base; and
a source-drain conductive layer 8 located on a side of the gate conductive layer 6 facing away from the base.

As shown in FIG. 7 and FIG. 12, the second-type touch fan-out lines are arranged on the first conductive layer.

In at least one embodiment of the present application, as shown in FIG. 8 and FIG. 9A, the first conductive layer includes a light-shielding layer 2. The light-shielding layer 2 is provided with a light-shielding pattern ZG located in the display area AA (as shown in FIG. 8) and the second-type touch fan-out lines located in the fan-out area (F area). The orthogonal projection of the light-shielding pattern ZG on the base 1 overlaps with the orthogonal projection of the active part of the transistor in the display area AA (the part of the active layer 4 that overlaps with the gate of the transistor) on the base 1. The part of the source-drain conductive layer 8 located in the display area AA includes touch signal TX lines, which are electrically connected to the touch electrodes in the display area and the touch fan-out lines T in the fan-out area.

In an exemplary embodiment, as shown in FIGS. 8, 9A, and 9B, the display substrate includes a light-shielding layer 2, a buffer layer 3, an active layer 4, a gate insulation layer (GI) 5, a gate conductive layer 6, an interlayer dielectric layer (ILD) 7, a source-drain conductive layer 8, a first planarization layer (or first organic insulation layer) PLN1 9, a first transparent conductive layer 12, a passivation layer 13, and a second transparent conductive layer 14, which are sequentially arranged on the base 1. The touch conductive layer 10 and the insulation layer 11 (PLN2) covering the touch conductive layer, as shown in FIG. 5 of the related art, are omitted.

In the embodiments of the present application, FIG. 10 is a cross-sectional view illustrating the electrical connection between the touch signal line TX in the display area AA and the touch fan-out line T in the fan-out area (F area). The touch signal line TX in the display area AA can be arranged in the source-drain conductive layer 8 and electrically connected to the second-type touch fan-out line arranged in the light-shielding layer 2 through a via.

In the embodiments of the present application, since the first-type touch fan-out lines adopt the dual-layer wiring method same as that adopted by the display fan-out lines S, the wring design space in the layer where the second-type touch fan-out lines are located is significantly released. Consequently, the second-type touch fan-out lines can utilize Mo material with a high resistance (the material of the light-shielding layer 2) while increasing their line width to reduce overall resistance thereof. This approach enables the resistance value of the first-type touch fan-out lines to be consistent with that of the second-type touch fan-out lines, minimizing resistance variations between adjacent touch fan-out lines T. In this way, under the premise of meeting the resistance requirements of the touch fan-out lines T, the use of Al process with production capacity bottleneck is avoided, thereby improving production capacity and reducing production costs. Furthermore, since the second-type touch fan-out lines are arranged on the first conductive layer (e.g., the light-shielding layer LS), two process required in related art for manufacturing the touch conductive layer 10 and the insulation layer 11 (PLN2) covering the touch conductive layer as shown in FIG. 5 can be eliminated. This significantly shortens the manufacturing process cycle and reduces costs.

In at least one embodiment of the present application, as shown in FIG. 4, the display substrate also includes:
a base 1;
a gate conductive layer 6 located on the base 1;
a source-drain conductive layer 8 located on a side of the gate conductive layer 6 facing away from the base; and
a second conductive layer 10 located on a side of the source-drain conductive layer 8 facing away from the base;

The second-type touch fan-out lines are arranged on the second conductive layer 10.

In at least one embodiment of the present application, the second conductive layer 10 includes a touch layer (TPM). The touch layer is provided with touch signal lines TX located in the display area AA and the second-type touch fan-out lines located in the fan-out area. The touch signal lines TX are electrically connected to the touch electrodes in the display area AA and the touch fan-out lines T in the fan-out area.

In an exemplary embodiment, the material of the source-drain conductive layer 8 can include aluminum (Al). For example, the source-drain conductive layer 8 can includes a single-layer structure of aluminum; or a laminated structure of molybdenum/aluminum/molybdenum (Mo/Al/Mo); or a laminated structure of titanium/aluminum/titanium (Ti/Al/Ti).

In an exemplary embodiment, the material of the gate conductive layer 6 can include aluminum (Al). For example, the gate conductive layer 6 can include a single-layer structure of aluminum; or a laminated structure of molybdenum/aluminum/molybdenum (Mo/Al/Mo); or a laminated structure of titanium/aluminum/titanium (Ti/Al/Ti).

In the embodiments of the present application, since the first-type touch fan-out lines adopt the dual-layer wiring method same as that adopted by the display fan-out lines, the wiring design space of the film layer where the second-type touch fan-out lines are located is significantly released. Therefore, the second-type touch fan-out lines can utilize Mo material with a higher resistance (the material of the touch layer) while increasing their line width to reduce the resistance thereof. This approach enables the resistance value of the first-type touch fan-out lines to be consistent with that of the second-type touch fan-out lines, minimizing resistance variations between adjacent touch fan-out lines T. In this way, under the premise of meeting the resistance requirements of the touch fan-out lines T, the second-type touch fan-out lines is avoided from being manufacture through the Al process with production capacity bottleneck, thereby improving production capacity and reducing production costs.

In at least one embodiment of the present application, the material of the second-type touch fan-out lines includes molybdenum (Mo), a thickness of the second-type touch fan-out lines is greater than 500 Å and less than or equal to 3000 Å, and the line width of the second-type touch fan-out lines ranges from 3 μm to 6 μm.

For example, the thickness of the film layer where the second-type touch fan-out lines T are located (the touch layer or the light-shielding layer) is greater than 500 Å and less than or equal to 3000 Å, for example 800 Å, 900 Å, 1000 Å, 1100 Å, 1200 Å, 1300 Å, 1400 Å, 1500 Å, 1600 Å, 1700 Å, 1800 Å, 1900 Å, 2000 Å, 2100 Å, 2200 Å, 2300 Å, 2400 Å, 2500 Å, 2600 Å, 2700 Å, 2800 Å, 2900 Å.

For example, the thickness of the second-type touch fan-out lines is greater than or equal to 1000 Å and less than or equal to 2000 Å.

For example, when the second-type touch fan-out lines are arranged on the light-shielding layer, the line width of the second-type touch fan-out lines ranges from 4.5 μm to 6 μm, for example 5.0 μm, 5.5 μm, etc.

In at least one embodiment of the present application, under the premise of ensuring that the signal number transmitted by the touch fan-out lines T on the light-shielding layer LS is sufficient, the thickness of the light-shielding layer LS can be set to be greater than or equal to 1000 Å and less than or equal to 2000 Å. When the active layer 4 covers the light-shielding layer LS, the slope angle of the light-shielding layer LS is less than or equal to 60° to avoid film layer cracks or even fractures in the climbing position on the side of the light-shielding layer LS.

In at least one embodiment of the present application, as shown in FIG. 15, the minimum distance between all touch fan-out lines T and the base 1 is substantially equal to the minimum distance between the display fan-out lines S and the base 1. The display fan-out lines S and partial segments of each touch fan-out line T are arranged in the gate conductive layer (Gate), and other parts of each touch fan-out line T are arranged in the source-drain conductive layer SD. The above minimum distance refers to an average minimum distance, that is, for each display fan-out line S and touch fan-out line T, the average value of the minimum distance between different segments and the base 1 is substantially the same. The “minimum distance” refers to the distance in the direction perpendicular to the base 1.

For example, each display fan-out line S and touch fan-out line T includes a first segment XD1 and a second segment XD2 electrically connected. The first segment XD1 extends to the boundary between the display area AA and the fan-out area (F area), and the second segment XD2 is electrically connected to the driver chip IC.

The first segment XD1 and the second segment XD2 of the same fan-out line are arranged in different film layers. Adjacent first segments XD1 are arranged in different film layers, and adjacent second segments XD2 are arranged in different film layers.

The term “adjacent first segments XD1” refers to two first segments between which no other first segment XD1 exists. The meaning of “adjacent second segments XD2” is analogous and will not be repeated.

In an exemplary embodiment, as shown in FIG. 15, for the same fan-out line (including display fan-out line S and the touch fan-out line T), either the first segment XD1 or the second segment XD2 is arranged in the source-drain conductive layer SD, and the other one is arranged in the gate conductive layer (Gate). One of the adjacent first segments XD1 is arranged in the source-drain conductive layer SD, and the other one is arranged in the gate conductive layer (Gate). One of the adjacent second segments XD2 is arranged in the source-drain conductive layer SD, and the other one is arranged in the gate conductive layer (Gate).

In an exemplary embodiment, the length of the first segment XD1 is substantially equal to that of the second segment XD2.

The phrase “the length of the first segment XD1 is substantially equal to that of the second segment XD2” includes following situations: the length of the first segment XD1 is equal to the length of the second segment XD2; or, the difference between the lengths of the first segment XD1 and the second segment XD2 is less than or equal to 5% of a central value, where the central value is the average length of XD1 and XD2.

In the embodiments of the present application, by configuring the lengths of the first segment XD1 and the second segment XD2 to be approximately equal, the resistance variation among all fan-out lines with the first segment XD1 and the second segment XD2 can be minimized, allowing the resistance values of the fan-out lines to be consistent as soon as possible. This approach helps prevent signal transmission loss discrepancies between different fan-out lines caused by resistance variations, thereby improving signal transmission uniformity and ultimately enhancing the performance of the display substrate.

In the embodiments of the present application, as shown in FIG. 15, by configuring all touch fan-out lines T to adopt the dual-layer wring method same as that adopted by the display fan-out lines S, that is, each touch fan-out line T includes a first segment XD1 and a second segment XD2, with one of them located in the source-drain conductive layer (SD) and the other in the gate conductive layer (Gate), the resistance value of the first-type touch fan-out lines and that of the second-type touch fan-out lines tends to be consistent with each other, minimizing resistance variations between adjacent touch fan-out lines T. While meeting the resistance requirements of the touch fan-out lines T, this configuration also eliminates two process required in related art for manufacturing the touch conductive layer 10 and the insulation layer 11 (PLN2) covering the touch conductive layer as shown in FIG. 5. This significantly shortens the manufacturing process cycle and reduces costs.

An embodiment of the present application provides a display panel including the display substrate described above.

The specific structure of the display substrate included in the display panel can refer to the description in the preceding text, which will not be repeated here.

The display panel can be a touch display panel.

The display panel can be a liquid crystal display (LCD) panel. For example, the liquid crystal display panel may include a TN (Twisted Nematic) LCD panel, a VA (Vertical Alignment) LCD panel, an IPS (In Plane Switching) LCD panel, and an ADS (Advanced Super Dimension Switch) LCD panel.

In the display panel provided by the embodiments of the present application, by setting the distance D2 between at least some of the touch fan-out lines T and the base 1 of the display substrate in a direction perpendicular to the plane where the base 1 is located to be substantially equal to the distance D1 between the display fan-out lines S and the base 1 in the direction perpendicular to the plane where the base 1 is located, at least some of the touch fan-out lines T can be arranged on the same layer as the display fan-out lines S. This releases the design space for the touch fan-out lines. In the actual manufacturing process, at least some of the touch fan-out lines T can be prepared in the same manufacturing process as the display fan-out lines S. On the basis of ensuring a narrow bezel, the resistance requirements and transmission performance of the signal lines, this approach can reduce the production load, shorten the manufacturing cycle, and lower the material usage cost and manufacturing process cost.

The above are only specific implementation methods of the present application, but the scope of protection of the present application is not limited to this. Any changes or substitutions that can be easily thought of by those skilled in the technical field within the technical scope disclosed by the present application should be covered within the scope of protection of the present application. Therefore, the scope of protection of the present application should be based on the scope of protection of the claims.

1. A display substrate, comprising:
a display area;
a fan-out area located on one side of the display area;
multiple display fan-out lines and multiple touch fan-out lines are provided in the fan-out area, the display fan-out lines and the touch fan-out lines are electrically connected to a driver chip respectively;
wherein in a direction perpendicular to a plane where a base of the display substrate is located, a distance between at least some of the touch fan-out lines and the base is substantially equal to a distance between the display fan-out lines and the base.

2. The display substrate according to claim 1, wherein the touch fan-out lines comprise first-type touch fan-out lines and second-type touch fan-out lines, orthogonal projections of the display fan-out lines and orthogonal projections of the first-type touch fan-out lines on the base do not overlap with each other, and the orthogonal projections of the display fan-out lines and the orthogonal projections of the second-type touch fan-out lines on the base overlap with each other.

3. The display substrate according to claim 2, wherein a minimum distance between the first-type touch fan-out lines and the base is substantially equal to a minimum distance between the display fan-out lines and the base, and a minimum distance between the second-type touch fan-out lines and the base is less than the minimum distance between the display fan-out lines and the base.

4. The display substrate according to claim 2, wherein a minimum distance between the first-type touch fan-out lines and the base is substantially equal to a minimum distance between the display fan-out lines and the base, and a minimum distance between the second-type touch fan-out lines and the base is greater than the minimum distance between the display fan-out lines and the base.

5. The display substrate according to claim 3, wherein a number of the first-type touch fan-out lines is less than a number of the second-type touch fan-out lines;
wherein the first-type touch fan-out lines and the second-type touch fan-out lines are arranged in different film layers, and at least some of the first-type touch fan-out lines are arranged in a same film layer, and the second-type touch fan-out lines are arranged in a same film layer.

6. The display substrate according to claim 5, wherein each of the display fan-out lines and the first-type touch fan-out lines comprises a first segment and a second segment that are electrically connected, the first segment extends to a boundary between the display area and the fan-out area, and the second segment is electrically connected to the driver chip;
the first segment and the second segment of the same fan-out line are arranged in different film layers; adjacent first segments are arranged in different film layers, and adjacent second segments are arranged in different film layers.

7. The display substrate according to claim 6, wherein the number of the first-type touch fan-out lines is one-Mth of a total number of all touch fan-out lines, and M is a positive integer equal to or greater than 2;
all the touch fan-out lines are divided in a way that every M touch fan-out lines form a group, with one touch fan-out line in the group being the first-type touch fan-out line.

8. The display substrate according to claim 7, wherein the number of the first-type touch fan-out lines is one third of the total number of all touch fan-out lines; all the touch fan-out lines are divided in a way that a (3N+1)th touch fan-out line, a (3N+2)th touch fan-out line and a (3N+3)th touch fan-out line form a group;
wherein the (3N+1)th touch fan-out line and the (3N+3)th touch fan-out line are the second-type touch fan-out lines, and the (3N+2)th touch fan-out line is the first-type touch fan-out line; the orthogonal projections of the (3N+1)th touch fan-out line and the (3N+3)th touch fan-out line on the base overlap with the orthogonal projections of the display fan-out lines on the base, while the orthogonal projection of the (3N+2)th touch fan-out line on the base does not overlap with the orthogonal projections of the display fan-out lines on the base; N is an integer.

9. The display substrate according to claim 8, wherein the display area is provided with multiple touch electrode rows arranged in an array, and each touch electrode row comprises multiple touch electrodes;
all the touch electrode rows are divided in a way that a (3N+1)th row, a (3N+2)th row and a (3N+3)th row form a group, each group of touch electrode rows comprises a touch electrode row where all the touch electrodes are electrically connected to the first-type touch fan-out lines.

10. The display substrate according to claim 6, wherein the number of the first-type touch fan-out lines is one-Mth of a total number of all touch fan-out lines, and M is a positive integer equal to or greater than 2;
multiple touch fan-out lines arranged in a direction intersecting with a direction from the display area to the fan-out area form a touch fan-out line group, all the touch fan-out lines in some of the touch fan-out line groups are the first-type touch fan-out lines, and all the touch fan-out lines in some other touch fan-out line groups are the second-type touch fan-out lines.

11. The display substrate according to claim 10, wherein the fan-out area comprises a first central region and two first edge regions located on both sides of the first central region, a direction from the first central region to the first edge regions intersects with a direction from the display area to the fan-out area;
wherein some of the first-type touch fan-out lines are located in one of the first edge regions, and some other first-type touch fan-out lines are located in the other first edge region, and the second-type touch fan-out lines are located in the first central region.

12. The display substrate according to claim 11, wherein the display area is provided with multiple touch electrode columns arranged in an array, and each touch electrode column comprises multiple touch electrodes;
wherein the display area comprises a second central region and two second edge regions located on both sides of the second central region, a direction from the second central region to the second edge regions intersects with a direction from the display area to the fan-out area; some of the touch electrode columns are located in the second central region, and some other touch electrode columns are located in the second edge regions;
the touch electrode columns located in the second edge regions are electrically connected to the first-type touch fan-out lines located in the first edge regions in the direction from the display area to the fan-out area, and the touch electrode columns located in the second central region are electrically connected to the second-type touch fan-out lines located in the first central region.

13. The display substrate according to claim further comprising:
the base;
a first conductive layer located on the base;
a gate conductive layer located on a side of the first conductive layer facing away from the base; and
a source-drain conductive layer located on a side of the gate conductive layer facing away from the base;
wherein the second-type touch fan-out lines is arranged on the first conductive layer.

14. The display substrate according to claim 13, wherein the first conductive layer comprises a light-shielding layer, the light-shielding layer is provided with a light-shielding pattern located in the display area and the second-type touch fan-out lines located in the fan-out area; the orthogonal projection of the light-shielding pattern on the base overlaps with the orthogonal projection of an active part of a transistor in the display area on the base;
wherein a part of the source-drain conductive layer located in the display area is provided with touch signal lines, the touch signal lines are electrically connected to the touch electrodes in the display area and the touch fan-out lines in the fan-out area.

15. The display substrate according to claim 6 further comprising:
the base;
a gate conductive layer located on the base;
a source-drain conductive layer located on a side of the gate conductive layer facing away from the base; and
a second conductive layer located on a side of the source-drain conductive layer facing away from the base;
wherein the second-type touch fan-out lines are arranged on the second conductive layer.

16. The display substrate according to claim 15, wherein the second conductive layer comprises a touch layer, the touch layer is provided with touch signal lines located in the display area and the second-type touch fan-out lines located in the fan-out area; the touch signal lines are electrically connected to the touch electrodes in the display area and the touch fan-out lines in the fan-out area.

17. The display substrate according to claim wherein material of the second-type touch fan-out lines comprises molybdenum, a thickness of the second-type touch fan-out lines is greater than 500 Å, and less than or equal to 3000 Å, and a line width of the second-type touch fan-out lines is in a range of 3 μm to 6 μm.

18. The display substrate according to claim 14, wherein a slope angle of the light-shielding layer is less than or equal to 60°.

19. The display substrate according to claim 1, wherein the minimum distance between all the touch fan-out lines and the base is substantially equal to the minimum distance between the display fan-out lines and the base;
each of the display fan-out lines and the touch fan-out lines comprises a first segment and a second segment that are electrically connected, the first segment extends to a boundary between the display area and the fan-out area, and the second segment is electrically connected to a driver chip;
the first segment and the second segment of the same fan-out line are arranged in different film layers; adjacent first segments are arranged in different film layers, and adjacent second segments are located in different film layers.

20. A display panel, comprising the display substrate according to claim 1.
